(19) United States
(12) Patent Application Publication
(10) Pub. No.: US 2012/0193732 A1
(43) Pub. Date: Aug. 2, 2012

(54) MEMS DEVICE AND METHOD FOR FORMING THE SAME

(75) Inventors: XIAOJUN CHEN, Shanghai (CN); Pinghuan Wu, Shanghai (CN); Herb Huang, Shanghai (CN)

(73) Assignee: Semiconductor Manufacturing International (Shanghai) Corporation, Shanghai (CN)

(21) Appl. No.: 13/244,134

(22) Filed: Sep. 23, 2011

(30) Foreign Application Priority Data
Jan. 31, 2011 (CN) 201110034096.X

(51) Int. Cl. H01L 29/84; H01L 21/00

(52) U.S. Cl. 257/415; 438/50; 257/E21.001; 257/E29.324

(57) ABSTRACT

An MEMS device and a method for forming the same are provided. The MEMS device comprises a first interlayer dielectric layer on a semiconductor substrate; a cavity in the first interlayer dielectric layer; first openings in the first interlayer dielectric layer over the cavity and connected with the cavity, each first opening comprising a lower portion and an upper portion having non-aligned sidewalls, convex sections are formed in the first interlayer dielectric layer between the lower and upper portions; an electrode being suspended in the cavity and movable relative to the substrate; a second interlayer dielectric layer on the first interlayer dielectric layer; second openings in the second interlayer dielectric layer and connected with the first openings, each second opening is disposed at a location that does not extend past the convex section; a third interlayer dielectric layer fully filling at least the second openings to seal the cavity.

### CROSS-REFERENCES TO RELATED APPLICATIONS

The present application claims the priority of Chinese Patent Application No. 201110034096.X, entitled “MEMS DEVICE AND METHOD FOR FORMING THE SAME”, and filed on Jan. 31, 2011, the entire disclosure of which is incorporated herein by reference.

### FIELD OF THE INVENTION

The present invention generally relates to the field of semiconductor technology, and more particularly, to an MEMS device and a method for forming an MEMS device.

### BACKGROUND OF THE INVENTION

Microelectromechanical systems (MEMS) technology includes the design, process, manufacturing, measurement and control technique of micro/nanotechnology materials. An

MEMS device is a micro system wherein mechanical components, optical systems, drive elements and electric control systems are integrated in a whole unit. For example, MEMS devices are used in position sensors, swiveling mechanisms or inertial sensors, acceleration transducers, gyroscopes, sound sensors, silicon microphones, accelerometers, display systems, and others.

A conventional MEMS device includes an MEMS structure (e.g., a movable electrode suspended from a substrate) disposed in a cavity and movable relative to the substrate. The process of forming the MEMS device includes two main steps, namely, forming the cavity and sealing the cavity.

FIGS. 1-3 are schematic cross-sectional views of intermediate structures in a method for forming an MEMS device, as known in the prior art. As shown in FIG. 1, an MEMS device includes a semiconductor substrate 100. Semiconductor substrate 100 has a drive circuit formed therein (not shown). The drive circuit is used to drive a movable electrode that is subsequently formed in the cavity on the substrate.

A sacrificial layer 103 is formed on a surface of the semiconductor substrate 100. Thereafter, a movable electrode 102 and a conductive plug 101 are formed in the sacrificial layer 103. The conductive plug 101 is electrically connected with the drive circuit in the semiconductor substrate 100 and the conductive plug 101 is electrically connected with the movable electrode 102.

Thereafter, an interlayer dielectric layer 104 is formed on the semiconductor substrate 100 and the sacrificial layer 103. Following the formation of the interlayer dielectric layer 104, regions of the interlayer dielectric layer 104 are selectively etched to form openings in the interlayer dielectric layer 104. The openings expose the sacrificial layer 103 and are used for removing the sacrificial layer 103 in subsequent steps, as shown in FIG. 2.

A cavity is formed in the interlayer dielectric layer 104 using the openings to remove the sacrificial layer 103 through an ashing process. The movable electrode 102 is suspended in the cavity and may move relative to the substrate, as shown in FIG. 3.

Finally, an insulating layer 105 is formed in the openings and on the interlayer dielectric layer 104 through a deposition process. The insulating layer 105 fills at least the openings to completely seal the cavity.

However, the reliability of an MEMS device thus formed is low. The reason being that parts of the insulating layer may be deposited on the surface of the MEMS electrode while sealing the cavity by filling the openings. In the process of sealing the MEMS device, parts of the insulation layer may come in contact with the electrode and affects the proper operation of the movable electrode, thereby lowering the reliability of the MEMS device.

Because the openings are formed directly over the electrode 102, parts of the insulating layer may reach and adhere to the surface of the electrode 102 through the openings while depositing the insulating layer.

Furthermore, because of a lack of a necessary shielding layer against electromagnetic interference, the electrode 102 fabricated using the conventional MEMS technique is vulnerable to electromagnetic interference, thereby rendering the operation of the MEMS device unstable.

In addition, due to a limited depth-to-width ratio of the openings, gas produced in the ashing process for removing the sacrificial layer may not be fully discharged through the openings in time, thereby reducing the efficiency of the ashing process.

US patent application No. US20070876107 discloses methods for forming MEMS devices. However, it is found the disclosed methods may not work properly and the thus formed MEMS devices may have low reliability. For these and other reasons, there is a need for the present invention.

### BRIEF SUMMARY OF THE INVENTION

Embodiments of the present invention provide an MEMS device and a method for forming the same, capable of preventing undesired deposition of insulating material to the surfaces of a movable electrode and shielding the electrode from external electromagnetic interference.

In an embodiment, as described below, an MEMS device includes a substrate, a first interlayer dielectric layer on a surface of the substrate, a cavity in the first interlayer dielectric layer, and a plurality of first openings in the first interlayer dielectric layer disposed over the cavity, the first openings are connected with the cavity, and each opening includes an upper portion and a lower portion, the lower portion is closer to the substrate than the upper portion, the upper and lower portions have sidewalls that are not aligned to each other, so that convex sections (stepped cross-sections) are formed between the lower and upper portions, and the convex sections are exposed in the upper portion. The MEMS device further includes an electrode that is coupled to a drive circuit in the substrate through a conductive plug, the electrode has one end that is suspended in the cavity and another end coupled to the conductive plug, the electrode can thus move relative to the substrate. In addition, the MEMS device includes a second interlayer dielectric layer on the first interlayer dielectric layer and a plurality of second openings in the second interlayer dielectric layer, the second openings are connected with the first openings, and disposed in a location within the first openings and not extending beyond a boundary determined by the convex sections associated therewith. The MEMS device also includes a third interlayer dielectric layer that completely fills the second openings to seal the cavity.

Optionally, each first opening has at least two portions: the lower portion and the upper portion. The lower and upper portions have different dimensions between them. Optionally, the upper portion is larger than the lower portion in width in order to form one or more stepped cross-sections (convex sections) in the first interlayer dielectric layer.

Optionally, the first openings comprise a T-sectional shape and/or an inverted L-sectional shape.

Optionally, the third interlayer dielectric layer completely fills the second openings and covers the second interlayer dielectric layer.

The MEMS device may further include a shielding layer overlying the third interlayer dielectric layer. The shielding layer may include a metallic material suitable for EMI shielding and having a thickness ranging from about 0.05 μm to about 5 μm.

In accordance with embodiments of the present invention, a method for forming an MEMS device includes the steps of: providing a semiconductor substrate; forming a first interlayer dielectric layer on the semiconductor substrate; forming a cavity in the first interlayer dielectric layer, the cavity contains an electrode that has one end coupled to a conductive plug and another end suspended over the substrate and movable relative to the substrate. The method further includes forming a plurality of first openings in the first interlayer dielectric layer over the cavity, the first openings are connected with the cavity, each first opening includes a lower portion and an upper portion, the lower portion is closer to the semiconductor substrate than the upper portion, the lower and upper portions have sidewalls that are not aligned with each other, so that convex sections are formed in the first interlayer dielectric layer between the lower and upper portions, and the convex sections are exposed in the upper portions. The method also includes the steps of forming a second interlayer dielectric layer on the first interlayer dielectric layer; forming a plurality of second openings in the second interlayer dielectric layer, the second openings are connected with the first openings and disposed at a location within the first openings and do not extend past the convex sections; and depositing a third interlayer dielectric layer in the second openings to seal the cavity.

Optionally, the first openings have different dimensions between them. Optionally, the upper portion of the first opening is wider than the lower portion in order to form at least one stepped cross-section. Optionally, the lower portion includes a width ranging from about 0.1 μm to about 1 μm, and the upper portion is wider than the lower portion. Optionally, the upper portion includes a width ranging from about 0.1 μm to about 1 μm.

Optionally, the first interlayer dielectric layer or the second interlayer dielectric layer comprises a thickness ranging from about 0.5 μm to about 5 μm.

The method for forming an MEMS device further includes forming a shielding layer on the third interlayer dielectric layer.

Optionally, the shielding layer is made of a metallic material suitable for EMI shielding and having a thickness ranging from about 0.05 μm to about 5 μm.

Optionally, forming the cavity includes the steps of: forming a first sacrificial layer on a surface of the semiconductor layer, including forming the conductive plug and the electrode in the first sacrificial layer, the electrode being coupled to a drive circuit through the conductive plug; patterning and etching the first interlayer dielectric layer to selectively expose surfaces of the first sacrificial layer over the electrode; depositing a second sacrificial layer to cover the exposed surfaces of the first sacrificial layer, the second sacrificial layer has a surface that is substantially planar with the first interlayer dielectric layer; forming the second interlayer dielectric layer on the first interlayer dielectric layer, wherein the second interlayer dielectric layer covers the second sacrificial layer; selectively etching the second interlayer dielectric layer to form the second openings; and removing the second sacrificial layer and the first sacrificial layer through the second openings to form the cavity in the first interlayer dielectric layer.

Optionally, the first sacrificial layer and the second sacrificial layer are removed by an ashing process.

Optionally, the first sacrificial layer and the second sacrificial layer are made of amorphous carbon or photoresist.

Technical solutions provided by the present invention have many advantages over conventional techniques. For example, the MEMS device provided by the present invention includes a first interlayer dielectric layer on a semiconductor substrate, the first interlayer dielectric layer contains a cavity therein. The cavity includes an electrode coupled to a conductive plug. First openings are formed in the first interlayer dielectric layer and connected with the cavity. Each first opening has a lower portion and an upper portion. The lower portion is closer to the semiconductor substrate than the upper portion. The lower and upper portions have non-aligned sidewalls. Convex (stepped) sections are formed in the first interlayer dielectric layer between the lower and upper portions. The convex sections are exposed at the upper portion. The convex sections protect the cavity and prevent the third interlayer dielectric layer from being deposited on surfaces of the electrode while sealing the cavity with the third interlayer dielectric layer, so that the electrode will not be contaminated by the third interlayer dielectric layer and will work properly and the reliability of the MEMS device will be improved.

Further, each of the first openings can have a different shape and dimension, and each first opening is connected with at least one second opening having an adequate size. Consequently, gas produced in the ashing process may form convection between the cavity and the space outside the device, the convection improves the removal of the gas produced in the ashing process, accelerates the ashing process and forces the gas produced in the ashing process completely out of the cavity.

Additionally, the MEMS device according to the present invention includes a shielding layer overlying the third interlayer dielectric layer. The shielding layer may include a metallic material suitable for electromagnetic interference (EMI) shielding to protect the electrode from external electromagnetic interference, thereby increasing the MEMS device EMI immunity and reliability.

### BRIEF DESCRIPTION OF THE DRAWINGS

FIGS. 1-3 are schematic cross-sectional views of intermediate structures illustrating the processing stages of forming an MEMS device, as known in the prior art;

FIG. 4 is a flow chart of steps performed to form an MEMS device according to an embodiment of the present invention; and

FIGS. 5-10 are schematic cross-sectional views of intermediate structures for illustrating a method shown in FIG. 4.

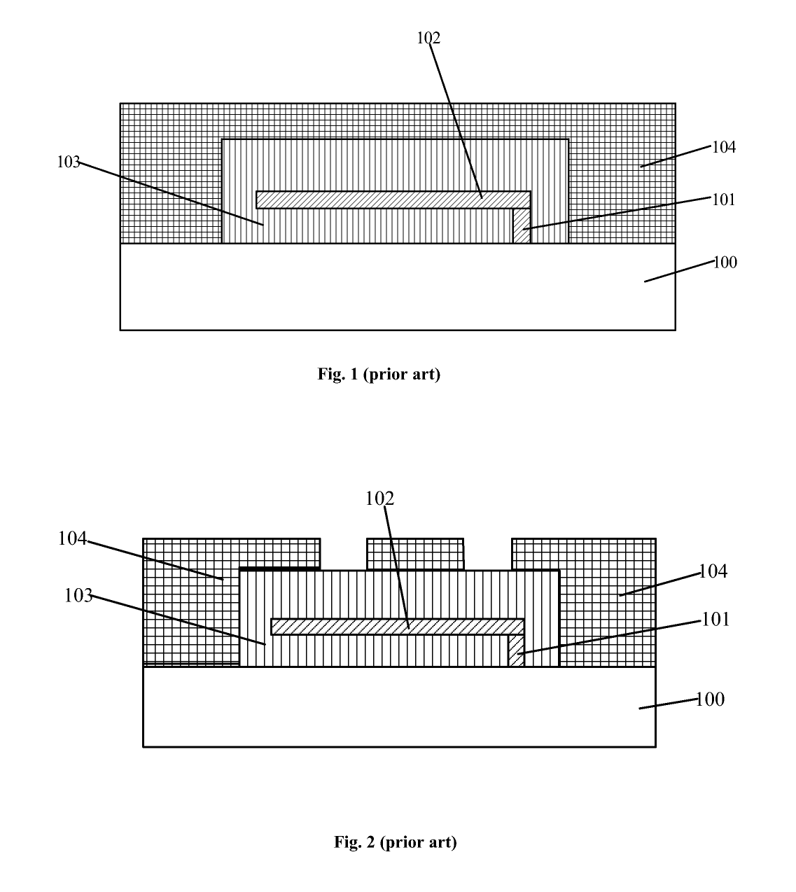

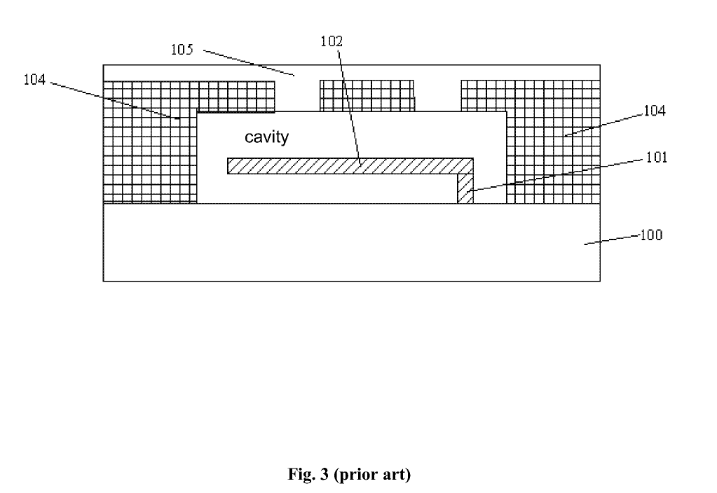

### DETAILED DESCRIPTION OF THE INVENTION

In the following detailed description, reference is made to the accompanying drawings which form a part hereof, and in which is shown by way of illustration specific embodiments in which the invention may be implemented. The term “upper”, “lower”, “vertical”, “horizontal”, “depth”, “height”, “width”, “top”, “bottom”, etc., is used with reference to the orientation of the Figures being described. Because components of embodiments of the present invention can be positioned in a number of different orientations, the term is used for purposes of illustration and is not limiting.

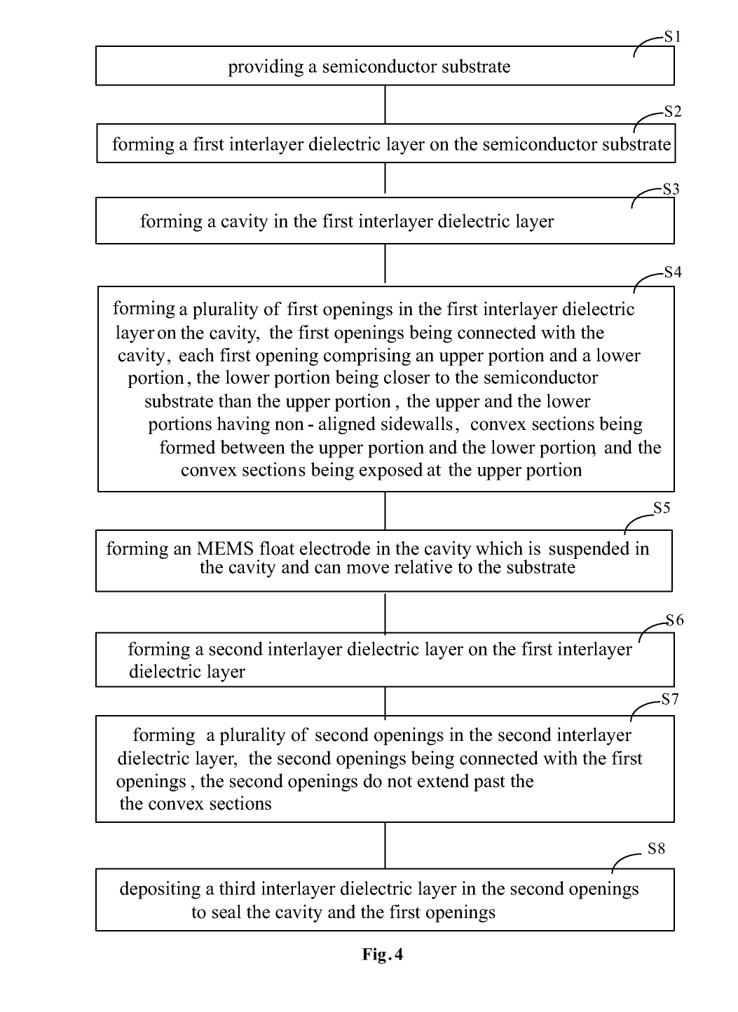

FIG. 4 is a flow chart of a method for forming an MEMS device according to an embodiment of the present invention. Exemplary flowchart in FIG. 4 is shown as including the following steps:

S1: providing a semiconductor substrate having a drive circuit therein;

S2: forming an interlayer dielectric layer on the semiconductor substrate;

S3: forming a cavity in the interlayer dielectric layer, the cavity having an electrode coupled to the drive circuit via a conductive plug;

S4: forming a plurality of first openings in the first interlayer dielectric layer over the cavity, the first openings are connected with the cavity, each opening includes an upper portion and a lower portion, the lower portion is closer to the semiconductor substrate than the upper portion, the lower portion and the upper portion have non-aligned sidewalls, convex sections are formed in the first interlayer dielectric layer and between the upper portion and the lower portion, and the convex sections are exposed at the upper portion;

S5: forming an electrode in the cavity, which is suspended in the cavity and may move relative to the semiconductor substrate;

S6: forming a second interlayer dielectric layer on the first interlayer dielectric layer;

S7: forming a plurality of second openings in the second interlayer dielectric layer, which are connected with the first openings and each second opening is disposed at a location that does not extend past the convex sections; and

S8: depositing a third interlayer dielectric layer in the second openings to seal the cavity and the first openings.

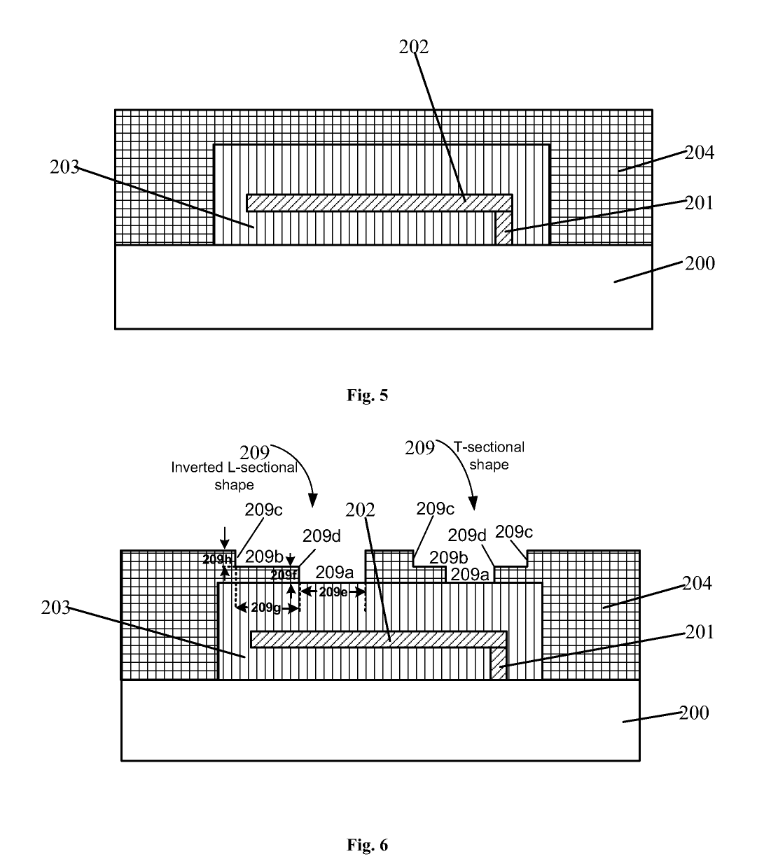

FIGS. 5-10 are schematic cross-sectional views for illustrating a method for forming an MEMS device shown in FIG. 4.

First, a semiconductor substrate 200 is provided. The semiconductor substrate 200 is made of semiconductor materials such as silicon or silicon germanium, as shown in FIG. 5. In the following description, the material of the semiconductor substrate 200 is silicon.

A drive circuit is formed in the semiconductor substrate 200 (not shown). The drive circuit is used to provide electric signals to an electrode that is subsequently formed.

Referring still to FIG. 5, a first sacrificial layer 203 is formed on a surface of the semiconductor substrate 200. A conductive plug 201 and an electrode 202 are formed in the first sacrificial layer 203. The conductive plug 201 is coupled to the drive circuit in the semiconductor substrate 200. The conductive plug 201 is electrically coupled to an end of the electrode 202.

Following the formation of the first sacrificial layer, a first interlayer dielectric layer 204 is formed on the first sacrificial layer 203 and on the semiconductor substrate to completely surround the first sacrificial layer. The first sacrificial layer 203 is then removed to form a cavity in the first interlayer dielectric layer. In order to protect the electrode 202, the conductive plug 201, the semiconductor substrate 200 and the first interlayer dielectric layer from being damaged while removing the first sacrificial layer 203, the first sacrificial layer 203 should be made of materials having a different etching selectivity ratio than that of the MEMS float electrode 202, the conductive plug 201, the semiconductor substrate 200 and the first interlayer dielectric layer.

In an embodiment of the present invention, the first sacrificial layer 203 is made of amorphous carbon. The first sacrificial layer 203 may be formed by a plasma enhanced chemical vapor deposition process. In another embodiment of the present invention, the sacrificial layer 203 may be made of photoresist and be formed by coating and development processes. The first sacrificial layer 203 will be removed by an ashing process in subsequent steps.

A thickness and a surface area of the sacrificial layer 203 determine the volume or space of the cavity to be formed. The cavity should have an adequate volume or space to accommodate the movement of the electrode. In an example embodiment, the size of the movable electrode determines the cavity space. In an embodiment, the thickness of the MEMS device determines the maximum thickness range of the first sacrificial layer 203.

Techniques for forming the first sacrificial layer 203, the electrode 202 and the conductive plug 201 in the sacrificial layer 203 have been disclosed in the prior art and are known to those skilled in the art. For the sake of brevity, they will not be described herein.

As shown in FIG. 5, the first interlayer dielectric layer 204 is formed on the semiconductor substrate 200 and on the first sacrificial layer 203. The first interlayer dielectric layer 204 surrounds the first sacrificial layer 203. In subsequent steps, after the first sacrificial layer 203 is removed, the cavity will be formed in the first interlayer dielectric layer 204. The first interlayer dielectric layer 204 can be made of electric insulating materials which include silicon nitride, silicon oxide, silicon carbide or silicon nitride oxide. In a specific embodiment, the first interlayer dielectric layer 204 is made of silicon oxide. The first interlayer dielectric layer 204 may be formed by a chemical vapor deposition process.

After the first interlayer dielectric layer 204 is formed, a planarization process is performed to enable the first interlayer dielectric layer 204 to have a flat surface, thereby benefiting subsequent steps. The planarization process may be a chemical mechanical polishing process.

Following the planarization process, openings are formed in a region of the first interlayer dielectric layer 204 that covers the top surface of the sacrificial layer 203. The openings are used for removing the first sacrificial layer 203. For a fully removal of the first sacrificial layer 203, the depth of the openings need to be adjusted based on the thickness and the size of the first sacrificial layer 203, and the thickness of the first interlayer dielectric layer 204 covering the top of the first sacrificial layer 203 should be greater than the depth of the opening. At the same time, the thickness of the first interlayer dielectric layer 204 covering the top of the first sacrificial layer 203 should not be too large, in order to obtain a thin and small MEMS device. In an embodiment of the present invention, the thickness of the first interlayer dielectric layer 204 covering the top of the first sacrificial layer 203 ranges from about 0.1 μm to about 5 μm.

Then, an etching process is proceeded to form first openings 209 in the first interlayer dielectric layer 204 on top of the cavity, as shown in FIG. 6. Each opening 209 has a lower portion 209a and an upper portion 209b. The lower portion 209a is closer to the semiconductor substrate 200 than the upper portion 209b. The lower portion and the upper portion have non-aligned sidewalls 209c, and convex sections (stepped cross-sections) 209d are formed in the first interlayer dielectric layer between the lower portion and the upper portion. The convex sections are exposed at the upper portion of the openings. The convex sections are parts of the first interlayer dielectric layer 204 and cover the first sacrificial layer 203. The convex sections are used for protecting the electrode that is formed in subsequent process steps, as will be described below. The convex sections will prevent a third interlayer dielectric layer from being deposited onto surfaces of the electrode in subsequent steps, as will be described below. The openings 209 may have a T-sectional shape, an inverted L-sectional shape or other stepped cross-sectional shapes. The sidewalls of the lower portion and the upper portion must not be aligned, i.e., the lower and upper portions have different size and the upper portion is larger than the lower portion, to ensure that the convex (stepped) sections are formed between the lower and upper portions, and the convex sections are exposed at the upper portion, as shown in FIG. 6. The first sacrificial layer 203 is removed then through the openings 209 in subsequent process steps.

In an embodiment of the present invention, the lower portion has a width 209e ranging from about 0.1 μm to about 1 μm, and a depth 209f ranging from about 0.1 μm to about 5 μm; the upper portion has a width 209g ranging from about 0.1 μm to about 1 μm, and a depth 209h ranging from about 0.1 μm to about 5 μm.

As shown in FIG. 6, openings 209 can have different shapes and sizes. Due to the different sizes and shapes of the openings 209, convection may be formed between the cavity thus formed and the external space of the MEMS device during the process of removal of the first sacrificial layer 203 by ashing, thereby accelerating the gas discharge produced in the ashing process, increasing the ashing process speed or reducing the ashing time and preventing the gas produced in the ashing process from remaining in the cavity.

It should be noted that any number of openings having different sizes and shapes may be formed in the first interlayer dielectric layer 204 over the electrode 202 based on the process needs to further increase the speed of the ashing process or reduce the time for removing the first sacrificial layer 203, and to prevent the gas produced in the ashing process from being remained in the cavity.

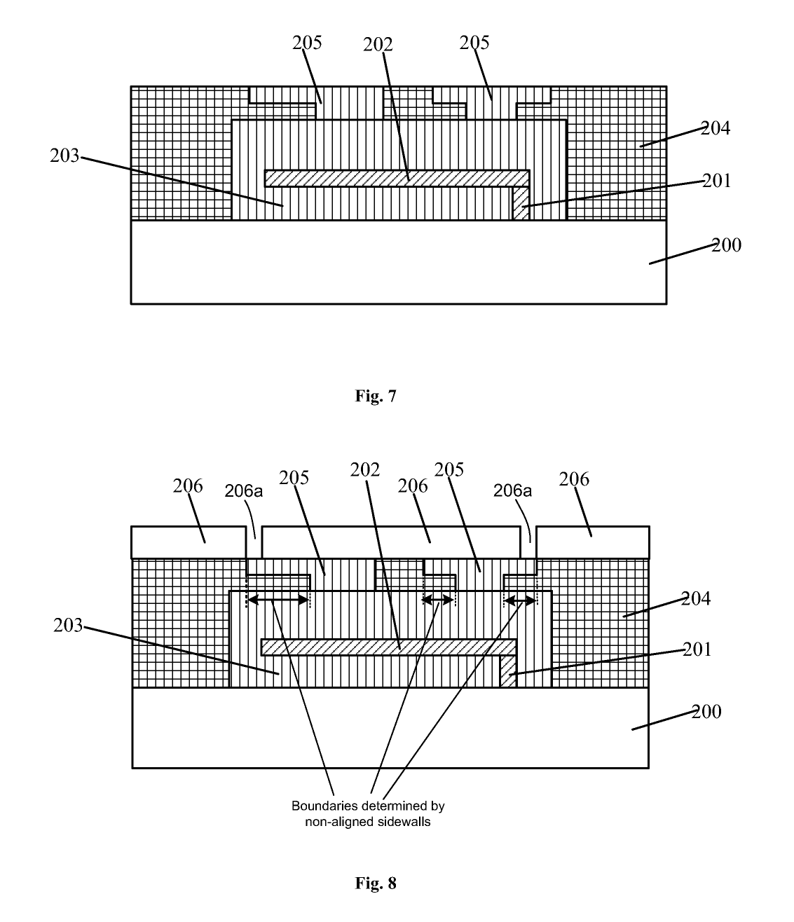

Then, a second sacrificial layer 205 is formed in the opening groups 209, as shown in FIG. 7. The second sacrificial layer 205 completely fills the openings 209, and becomes a part of the first sacrificial layer 203.

A second interlayer dielectric layer 206 will be formed on the second sacrificial layer 205 and on the first interlayer dielectric layer 204. Then, second openings are formed in the second interlayer dielectric layer 206. The second openings may be formed by photolithography and etching. Thereafter, the second sacrificial layer 205 and the first sacrificial layer 203 will be removed through the second openings. In order to protect the first interlayer dielectric layer 204 from being damaged while removing the second sacrificial layer 205, the second sacrificial layer 205 should be made of materials having a different etching selectivity ratio than the first interlayer dielectric layer 204.

In an embodiment of the present invention, the first sacrificial layer 203 and the second sacrificial layer 205 may be made of the same material, thus the first sacrificial layer 203 and the second sacrificial layer 205 may be removed together in the same etching process, thus, the steps of manufacturing a MEMS device can be simplified. In an embodiment, the second sacrificial layer 205 is made of amorphous carbon. The second sacrificial layer 205 may be formed by a chemical vapor deposition process. After the second sacrificial layer 205 is formed, a planarization process is performed to enable the first interlayer dielectric layer 204 to be substantially flush (coplanar) with the second sacrificial layer 205. The planarization process may be a chemical mechanical polishing process.

Then, a second interlayer dielectric layer 206 is formed over the first interlayer dielectric layer 204, as shown in FIG. 8. The second interlayer dielectric layer 206 covers the second sacrificial layer 205. In an embodiment, the second interlayer dielectric layer 206 is made of electric insulating materials which may include silicon nitride, silicon oxide, silicon carbide or silicon nitride oxide. In an embodiment, the second interlayer dielectric layer 206 is made of silicon oxide. The second interlayer dielectric layer 206 may be formed by a chemical vapor deposition process and has a thickness ranging from about 0.1 μm to about 5 μm.

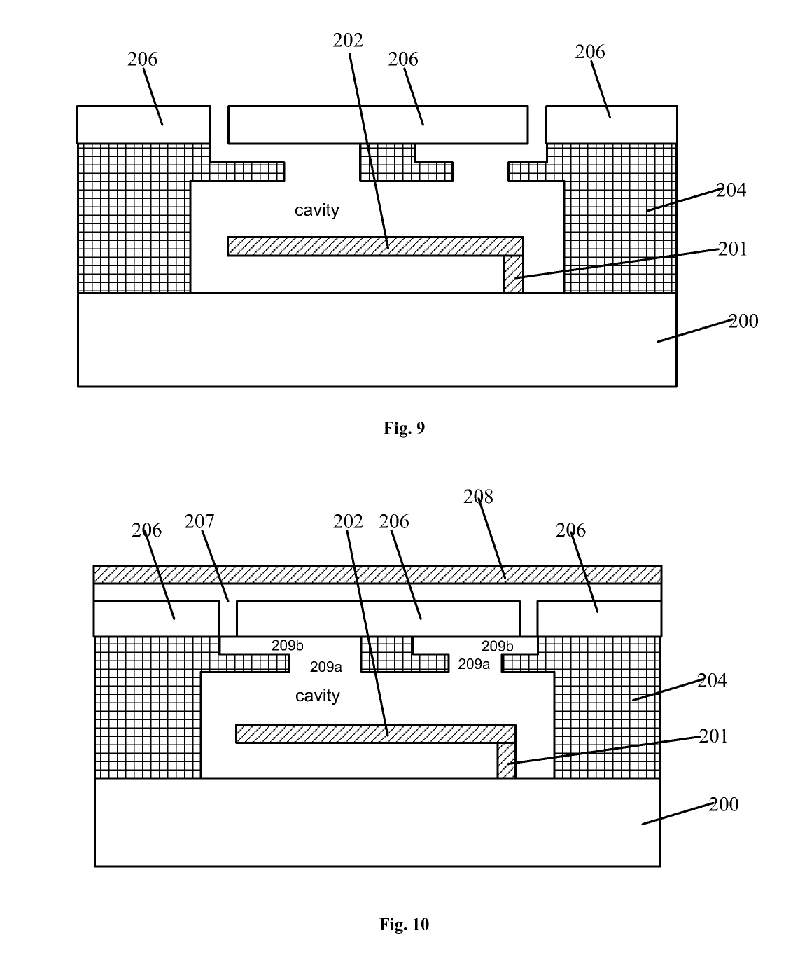

Thereafter, second openings 206a are selectively formed in the second interlayer dielectric layer 206 by etching. The second openings 206a are connected with the openings 209, and are thus disposed within the openings 209. It should be noted that each second opening 206a is disposed within a boundary determined by the non-aligned sidewalls of the upper and lower portions of opening 209 and the convex sections. In other words, the second openings 206a should not extend past the convex sections and be placed over the lower portion. Second openings 206a together with openings 209 are used to remove the first sacrificial layer 203 and the second sacrificial layer 205 for forming a cavity in the first interlayer dielectric layer 204, as shown in FIG. 9. Following the formation of the cavity, a third interlayer dielectric layer is deposited into the second openings by a chemical vapor deposition process. The convex sections in the first interlayer dielectric layer 204 formed by the upper and lower portions of openings 209 thus prevent the third interlayer dielectric layer from entering the cavity.

As described above, the second openings 206a should be placed over the first openings 209 and the location of the second openings should not go beyond the boundary determined by the convex sections, i.e., the second openings should not be placed over the lower portion of opening 209 so that the convex sections of the first interlayer dielectric layer 204 can stop the second interlayer dielectric layer 206 from entering the cavity through the second opening. The size of each second opening 206a is determined by the size of the associated first opening 209 in an embodiment.

As shown in FIG. 9, a cavity is formed in the first interlayer dielectric layer 204 by removing the first sacrificial layer and the second sacrificial layer through the second openings in the second interlayer dielectric layer 206. The cavity is connected with the openings 209. In an embodiment, the first sacrificial layer and the second sacrificial layer are removed by an ashing process. The ashing process can be proceeded using plasma of oxygen or nitrogen and at a temperature ranging from about 100 degree centigrade to about 300 degree centigrade. Within this temperature range, the first sacrificial layer and the second sacrificial layer may be transformed into gas and can be completely removed.

In an embodiment, two openings 209 having different sizes are formed in the first interlayer dielectric layer 204 over the electrode 202, and second openings 206a associated with the openings 209 are formed in the second interlayer dielectric layer 206. The second openings work together with their associated first openings during the ashing process, and convection is generated between the cavity being formed and space exterior to the MEMS device, thereby accelerating the discharge of gas produced by the ashing process, increasing the ashing process speed, reducing the ashing process time and preventing the gas produced by the ashing process from remaining in the thus formed cavity.

Then, a third interlayer dielectric layer 207 is formed on the second interlayer dielectric layer 206 by a chemical vapor deposition process. The third interlayer dielectric layer 207 completely fills at least the second openings in the second interlayer dielectric layer 206 and seals the cavity, as shown in FIG. 10. Thanks to the convex sections in the first interlayer dielectric layer and the second openings not extending beyond the convex sections, the third interlayer dielectric layer formed by a chemical vapor deposition process while filling the second openings will be stopped by the surfaces of the convex sections between the upper and lower portions and will not enter into the cavity.

In an embodiment, after the cavity is sealed, a shielding layer 208 is formed on the third interlayer dielectric layer 207. The shielding layer 208 is used to shield the electrode 202 from external electromagnetic interference (EMI), thereby an EMI immunity and reliable operation of the MEMS device can be obtained.

In an embodiment, the shielding layer comprises a metallic material having a good EMI shielding characteristic and a thickness ranging from about 0.05 μm to about 5 μm. In an embodiment, the metal shielding layer 208 includes at least one of aluminum, titanium, nickel, tungsten, silver, chromium, copper and gold.

In accordance with embodiments of the present invention, an MEMS device includes a semiconductor substrate 200, a first interlayer dielectric layer 204 on the semiconductor substrate 200, a cavity in the first interlayer dielectric layer 204, and a conductive plug 201 in the cavity. An electrode 202 is suspended in the cavity, the electrode being coupled to the conductive plug 201 and movable relative to the semiconductor substrate in response to a signal from a drive circuit. A plurality of first openings 209 are formed in the first interlayer dielectric layer 204 over the cavity, the first openings 209 being connected with the cavity, each opening including a lower portion 209a and an upper portion 209b. The lower portion is closer to the semiconductor substrate 200 than the upper portion. In an embodiment, the lower and upper portions have non-aligned sidewalls. Convex sections are formed between the lower and upper portions in the first interlayer dielectric layer 204, and the convex sections are exposed at the second opening. A second interlayer dielectric layer 206 overlies the first interlayer dielectric layer 204 and above the cavity. A plurality of second openings in the second interlayer dielectric layer 206, the second openings being connected with the first openings. Each second opening is disposed at a location that does not extend beyond an associated convex section. A third interlayer dielectric layer 207 completely fills at least the second openings for sealing the cavity.

In an embodiment, the MEMS device further includes a shielding layer 208 overlying the third interlayer dielectric layer 207. The shielding layer 208 includes a metallic material having good EMI shielding performance to protect the electrode 202 from external electromagnetic interference.

In an embodiment, the shielding layer 208 has a thickness ranging from about 0.05 μm to about 5 μm. In an embodiment, the metallic material comprises one of aluminum, titanium, nickel, tungsten, silver, chromium, copper or gold.

In an embodiment, at least two openings having different sizes and/or shapes are formed over the electrode in the cavity. The openings may include a T-sectional shape or an inverted or lying L-sectional shape.

While an MEMS device having a T-sectional or an inverted or lying L-sectional shape has been described, other stepped cross-sectional shapes can also be employed that provide convex sections in the first interlayer dielectric layer formed between two or more portions in the first opening, the convex sections serve to prevent the third interlayer dielectric layer from being deposited on the surface of the electrode, thereby protecting the electrode from being contaminated by the third interlayer dielectric layer, so that the MEMS device will work properly and reliably.

While first openings having a lower portion and an upper portion are described, first openings with more than two portions can also be employed. The portions can have different sizes to form convex sections in the first interlayer dielectric layer to prevent the sealing layer (third interlayer dielectric layer) from contaminating the movable electrode contained in the cavity. Furthermore, the second openings disposed over the first openings should not be directly positioned over the electrode and should be adequately dimensioned to enable gases produced in the ashing process to form convection between the cavity and the space outside of the MEMS device, thereby accelerating the removal of gases produced in the ashing process, reducing ashing process time and forcing the gases produced in the ashing process out of the cavity.

In addition, the MEMS device includes a shielding layer disposed on the third (sealing) interlayer dielectric layer to seal the cavity. The shielding layer includes a metallic material having a good EMI performance to shield the electrode against electromagnetic interference, thereby increasing the reliability of the MEMS device.

The invention is disclosed, but not limited, by preferred embodiments as described above. It should be understood that these embodiments are illustrative and not limitative, those skilled in the art can make variations and modifications without departing from the scope of the invention. Therefore, any modifications, variations, and polishing based on the embodiments described herein is within the scope of the present invention.

What is claimed is:

1. An MEMS device comprising:
a substrate;
a first interlayer dielectric layer on a surface of the substrate;
a cavity in the first interlayer dielectric layer;
a plurality of first openings in the first interlayer dielectric layer disposed over the cavity, the first openings being connected with the cavity, each first opening comprising an upper portion and a lower portion, the lower portion being closer to the substrate than the upper portion, the upper and lower portions having non-aligned sidewalls, convex sections being formed between the upper and lower portions, and the convex sections being exposed at the upper portion;
an electrode suspended in the cavity, the electrode being coupled with a drive circuit in the substrate through a conductive plug and movable relative to the substrate;
a second interlayer dielectric layer on the first interlayer dielectric layer;
a plurality of second openings in the second interlayer dielectric layer, the second openings being connected with the first openings, and disposed at a location not extending beyond the convex sections; and
a third interlayer dielectric layer completely filling the second openings.

2. The MEMS device according to claim 1, wherein the first openings comprise at least two openings.

3. The MEMS device according to claim 1, wherein the upper portion is larger than the lower portion.

4. The MEMS device according to claim 1, wherein the lower portion comprises a width ranging from about 0.1 μm to about 1 μm and a height ranging from 0.1 μm to about 5 μm.

5. The MEMS device according to claim 1, wherein the upper portion comprises a width ranging from about 0.1 μm to about 1 μm and a height ranging from 0.1 μm to about 5 μm.

6. The MEMS device according to claim 1, wherein the first interlayer dielectric layer comprises a thickness ranging from about 0.1 μm to about 5 μm.

7. The MEMS device according to claim 1, wherein the second interlayer dielectric layer comprises a thickness ranging from about 0.1 μm to about 5 μm.

8. The MEMS device according to claim 1, wherein the first openings have a T-sectional shape or an inverted L-sectional shape.

9. The MEMS device according to claim 1 further comprising:
a shielding layer disposed on the third interlayer dielectric layer.

10. The MEMS device according to claim 9, wherein the shielding layer is made of a metallic material and has a thickness ranging from about 0.05 μm to about 5 μm.

11. A method for forming an MEMS device, the method comprising:
providing a semiconductor substrate having a drive circuit;
forming a first interlayer dielectric layer on the semiconductor substrate;
forming a cavity in the first interlayer dielectric layer, the cavity having an electrode coupled to the drive circuit through a conductive plug;
forming a plurality of first openings in the first interlayer dielectric layer over the cavity, the first openings being connected with the cavity, each opening comprising an upper portion and a lower portion, the lower portion being closer to the semiconductor substrate than the upper portion, the upper and lower portions having non-aligned sidewalls, convex sections being formed between the upper and lower portions, the convex sections being exposed at the upper portion;
forming a second interlayer dielectric layer on the first interlayer dielectric layer;
forming a plurality of second openings in the second interlayer dielectric layer, the second openings being connected with the first openings and disposed at a location not extending beyond the convex sections; and
filling a third interlayer dielectric layer in the second openings.

12. The method according to claim 11, wherein the first openings comprise at least two openings having different sizes.

13. The method according to claim 11, the lower portion comprises a width ranging from about 0.1 μm to about 1 μm and a height ranging from 0.1 μm to about 5 μm.

14. The method according to claim 11, the upper portion comprises a width ranging from about 0.1 μm to about 1 μm and a height ranging from 0.1 μm to about 5 μm.

15. The method according to claim 11 further comprising:
forming a shielding layer on the third interlayer dielectric layer.

16. The method according to claim 15, wherein the shielding layer comprises a metallic material having a thickness ranging from about 0.05 μm to about 5 μm.

17. The method according to claim 11, wherein forming the cavity comprises:
forming a first sacrificial layer on a surface of the semiconductor substrate, comprising forming the conductive plug and the electrode in the first sacrificial layer, the electrode being coupled with a drive circuit in the semiconductor substrate through the conductive plug;
forming the first interlayer dielectric layer on the first sacrificial layer and on the semiconductor substrate to completely surround the first sacrificial layer;
patterning and etching the first interlayer dielectric layer to selectively expose surfaces of the first sacrificial layer above the electrode;
depositing a second sacrificial layer to cover the exposed surfaces of the first sacrificial layer, the second sacrificial layer having a surface substantially planar with a surface of the first interlayer dielectric layer;
selectively etching the second interlayer dielectric layer to form the second openings; and
removing the second sacrificial layer and the first sacrificial layer through the second openings to form the cavity in the first interlayer dielectric layer.

18. The method according to claim 17, wherein the removing the first sacrificial layer and the second sacrificial layer comprises an ashing process.

19. The method according to claim 17, wherein the first sacrificial layer and the second sacrificial layer comprise amorphous carbon or photoresist.

20. The method according to claim 11, wherein the first openings have T-sectional shapes or inverted L-sectional shapes.
